(19) United States
(12) Patent Application Publication
(10) Pub. No.: US 2008/0079456 A1
(43) Pub. Date: Apr. 3, 2008

(54) TEST HANDLER FOR TESTING SEMICONDUCTOR DEVICE AND METHOD OF TESTING SEMICONDUCTOR DEVICE USING THE SAME

(75) Inventor: Sung-soo LEE, Cheonan-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/778,160

(22) Filed: Jul. 16, 2007

(30) Foreign Application Priority Data
Oct. 2, 2006 (KR) 10-2006-0097406

(51) Int. Cl. G01R 31/26

(52) U.S. Cl. 324/765

(57) ABSTRACT

Provided is a test handler for testing a semiconductor device mounted in a test tray with a test head disposed separately below the test tray under predetermined testing condition at high or low temperature. The test handler includes a thermal isolator to maintain constant the predetermined testing condition at high or low temperature when the test chamber and the test head are separated. The thermal isolator is a shutter that is installed below the test chamber to seal or open the test chamber.

### CROSS-REFERENCE TO RELATED PATENT APPLICATION

This application claims the benefit of Korean Patent Application No. 10-2006-0097406, filed on Oct. 2, 2006, the disclosure of which is hereby incorporated by reference.

### BACKGROUND OF THE INVENTION

1. Field of the Invention

The present invention relates to a test handler for testing semiconductor devices and a method of testing semiconductor devices using the test handler. More particularly, the invention relates to a test handler promoting maintenance of a constant temperature within a test chamber, and a method of testing semiconductor devices using the test handler.

2. Description of Related Art

In general, semiconductor devices, also referred to as integrated circuits (ICs), include memory devices, non-memory devices, and modules which mount a plurality of ICs on a wiring substrate. Following fabrication but before being shipped to customers or being incorporated within a host device, semiconductor devices must pass through a series of test procedures. Many of these test procedures are highly specialized. In order to facilitate the speed, automation, and accuracy of some test procedures, one or more special device(s) generically referred to as a “tester” is used. Testers vary in size and application but may incorporate hardware and/or software resources.

Many testers include a transport processing unit, typically referred to as a “test handler.” Test handlers are designed to safely transport one or more semiconductor devices between test stations or from storage to a particular test station. The typical test handler is designed to place the semiconductor device(s) in a test tray within a test station (e.g., a test chamber), and facilitate execution of an electrical test by connecting the semiconductor device(s) to a test board or test head within the test station chamber. Tests are often conducted across a temperature range of between (e.g.,) −50° C. and +150° C. Once tested and classified as either acceptable or rejected, the semiconductor device(s) is discharged from the test station.

However, practical testing requires a significant throughput of tested devices. Further, a range of different semiconductor devices must be produced in various classes and physical configurations. Thus, a handling chamber within the test handler and the test head (or test board) within the testing station must be designed to mate and operate with one another. In view of the many different types of semiconductor devices being tested, this requirement means that the handling chamber and/or the test head must be frequently changed. Accordingly, it is difficult to properly maintain a high or low temperature within a test station chamber while changing out these elements. Unfortunately, it is also very important to maintain a constant high or low temperature in the test station chamber when the test head (test board or test socket) is being repaired, replaced, or when a tester operating defect is being addressed.

If the temperature within the test station chamber is not maintained at a constant level, it must be reheated or re-cooled to the defined test temperature. This can take a great deal of time and slow testing throughput. Accordingly, the working ratio for the tester and the corresponding productivity of the testing process decrease significantly.

### SUMMARY OF THE INVENTION

Embodiments of the invention provide a test handler capable of assisting in efforts to maintain constant testing temperatures for test station chamber when a test head or a test board must be replaced or repaired, or even when a defect in the testing procedure is being addressed. Embodiments of the invention also provide a method of testing semiconductor devices using such a test handler.

In one embodiment, the invention provides a test handler for testing a semiconductor device, the test handler comprising a test chamber testing the semiconductor device under a test temperature by electrically connecting the semiconductor device mounted in a test tray with a test head disposed under and separated from the test tray, wherein the test chamber includes a thermal isolator maintaining the test temperature constant when the test chamber is separated from the test head.

In another embodiment, the invention provides a test handler for testing a semiconductor device, the test handler comprising; a soak chamber preheating or pre-cooling the semiconductor device mounted in a test tray to a test temperature, a test chamber disposed to one side of the soak chamber, receiving the semiconductor device from the soak chamber, combining with a test head to electrically connect the semiconductor device during testing under the test temperature, and separating from the test head following testing of the semiconductor device, and an exit chamber disposed to one side of the test chamber, receiving the semiconductor device following testing and returning the semiconductor device to a normal temperature, wherein a thermal isolator installed in the test chamber maintains the test temperature constant while the test chamber is separated from the test head.

In another embodiment, the invention provides a test handler for testing a semiconductor device, the test handler comprising; a soak chamber preheating or pre-cooling the semiconductor device mounted in a test tray under a defined test temperature, a test chamber disposed to one side of the soak chamber, receiving the semiconductor device transported from the soak chamber in an X direction, and combining with a test head disposed below and separated from the test chamber during testing of the semiconductor device under the test temperature by movement of the test head in a Z direction, and an exit chamber disposed to one side of the test chamber, receiving the semiconductor device in the X direction, and returning the semiconductor device to a normal temperature, wherein the test chamber comprises a thermal isolator maintaining the test temperature constant when the test chamber is separated from the test head, the thermal isolator being installed in a body of the test chamber to move in a Y direction to seal or open the test chamber.

In another embodiment, the invention provides a method of testing a semiconductor device, the method comprising; preheating or pre-cooling the semiconductor device mounted in a test tray in a soak chamber at a test temperature, testing the semiconductor device in a test chamber under the test temperature by electrically connecting the semiconductor device with a test head installed separately from the test chamber, moving the test tray including the tested semiconductor devices to an exit chamber following testing, upon determining that the test head requires repair or change, or that a testing defect has occurred, separating the test head from the test chamber but maintaining the test temperature in the test chamber when the test chamber is separated from the test head.

### BRIEF DESCRIPTION OF THE DRAWINGS

Embodiments of the invention will be described with reference to the attached drawings in which:

FIG. (FIG.) 1 is a schematic view illustrating a test handler according to an embodiment of the invention;

FIG. 2 further illustrates the back side of the test handler shown in FIG. 1;

FIG. 3 further illustrates elements of the test handler during testing of a semiconductor device within the test chamber shown in FIG. 2;

FIG. 4 is a rear perspective view of a test handler in which a test chamber and a test head are combined according to an embodiment of the invention;

FIG. 5 is a rear perspective view further illustrating the test handler of FIG. 4 in which the test chamber and the test head are separated;

FIG. 6 is a plane view further illustrating the test chamber of FIG. 4, the test chamber including a thermal isolator according to an embodiment of the invention;

FIGS. 7 and 8 are perspective views further illustrating separated and combined states for the test chamber of FIG. 4; and

FIG. 9 is a flow chart summarizing a method of testing a semiconductor device using a test handler including a test chamber according to an embodiment of the invention.

### DESCRIPTION OF EMBODIMENTS

The present invention will now be described with reference to the accompanying drawings, in which exemplary embodiments of the invention are shown. The invention may, however, be embodied in many different forms and should not be construed as being limited to only the illustrated embodiments. Rather, the illustrated embodiments are provided so that this disclosure will be thorough and complete, and will fully convey the concept of the invention to those skilled in the art. In the drawings, the relative size of certain elements and regions may have been exaggerated for clarity of illustration.

An exemplary configuration for a test handler according to an embodiment of the invention will be described briefly with reference to FIGS. 1 through 3. The test handler described in relation to FIGS. 1 through 3 can be a horizontal or lateral test handler. Throughout the written description and drawings, like reference numerals denote like or similar elements.

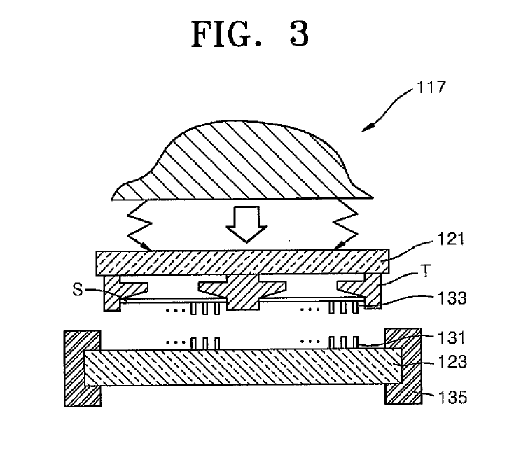

FIG. 1 is a schematic view of a test handler 100 according to an embodiment of the invention. Test handler 100 includes loading stockers 101 installed in a front portion 500 of test handler 100. Customer trays C, each mounting a plurality of semiconductor devices (S in FIG. 3) to be tested, are stacked on the loading stockers 101. Unloading stockers 103 are installed to the side of the test handler 100 next to the loading stockers 101 and accommodate tested semiconductor devices classified by test results in individual customer trays C.

Buffer units 105 are installed to one side of a middle portion 550 of test handler 100 and move forward and backward in order to temporarily accommodate transported semiconductor devices from the loading stockers 101. A changing unit 107 is disposed between the buffer units 105. Semiconductor devices to be tested are transported and mounted into test trays T. Then tested semiconductor devices from the test trays T are mounted back into the buffer units 105. A returning unit 109 accommodates and returns tested semiconductor devices between the changing unit 107 and a back portion 600 of the test handler 100.

A first pickup robot 111 is installed between the front portion 500 where the loading stocker 101 and unloading stocker 103 are arranged and the middle portion 550 where the changing unit 107 and buffer units 105 are arranged. A second pickup robot 113 is installed in the middle portion 550. The first pickup robot 111 and a second pickup robot 113 move along X and Y axes, and are adapted to pick up and transport semiconductor devices. The first pickup robot 111 transports semiconductor devices across the spaces between the loading stocker 101 and the unloading stocker 103 and the buffer units 105. The second pickup robot 113 transports semiconductor devices between the buffer units 105 and the changing unit 107.

A soak chamber 115, a test chamber 117, and an exit chamber 119 are installed in the back portion 600 of the test handler 100. The test trays T mounting semiconductor devices to be tested move from the soak chamber 115 to the exit chamber 119. The soak chamber 115 preheats or pre-cools the semiconductor devices mounted in the test rays T to a predetermined test temperature, for example, −50° C. to +150° C. before supplying the test trays T to the test chamber 117.

The semiconductor devices may be tested in the test chamber 117 under temperature ranging, for example, from −50° C. to +150° C. For testing, the semiconductor devices mounted in the test trays T are electrically connected to test sockets 125 of a test board 123 using a test plate 121. Then, the semiconductor devices tested in the test chamber 117 are returned to room temperature in the exit chamber 119.

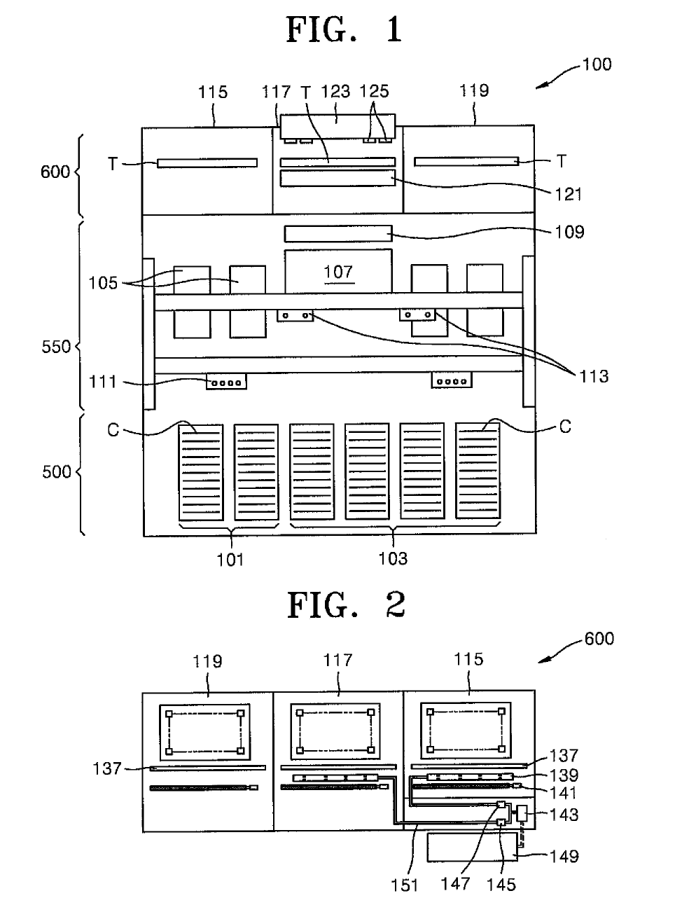

FIG. 2 further illustrates a back side of the test handler 100 shown in FIG. 1, and FIG. 3 further illustrates certain elements of test handler 100 during testing of the semiconductor devices in the test chamber 117 of FIG. 2.

A back portion 600 of test handler 100 includes soak chamber 115, test chamber 117, and exit chamber 119. A heating rod 137 is installed in test chamber 117 and soak chamber 115 to raise chamber temperatures. Additionally, a liquid nitrogen spray rod 139 having holes adapted to exhaust liquid nitrogen is installed to reduce chamber temperature. A ventilation fan 141 is installed to aid in the cooling or heating of the chambers.

When a high temperature test is required, heat generated by heating rod 137 is evenly applied to the test handler 100 (or at least test chamber 117) by means of ventilation fan 141. When a low temperature test is required, cooling liquid nitrogen supplied from an external source 149 through a liquid nitrogen supplying pipe 151 is applied to via liquid nitrogen spray rod 137 to bring reduce the temperature of at least test chamber 117.

A solenoid valve 143 is installed below soak chamber 115 to control the supply of liquid nitrogen to soak chamber 115 and/or test chamber 117. A first supply valve 145 may additionally be used to control the supply of liquid nitrogen to test chamber 117, and a second supply valve 147 may additionally be used to control the supply of liquid nitrogen to soak chamber 115 in conjunction with the solenoid valve 143.

As illustrated in FIG. 3, mechanical pressure is applied to test plate 121 when the test trays T enter test chamber 117. Semiconductor devices are arranged on an upper portion of the test board 123 which is connected to the test head 135 in order to electrically connect each semiconductor device S in the test trays T with the test sockets 125 of the test board 123.

The test head 135, test board 123, test socket 125 connected to test head 135 may be installed separately from the main body of test handler 100, and may function as an interface with test handler 100. In FIG. 3, contact terminals 131 extended from test socket 125 of test board 123. External connection terminals 133 extended from the semiconductor device S.

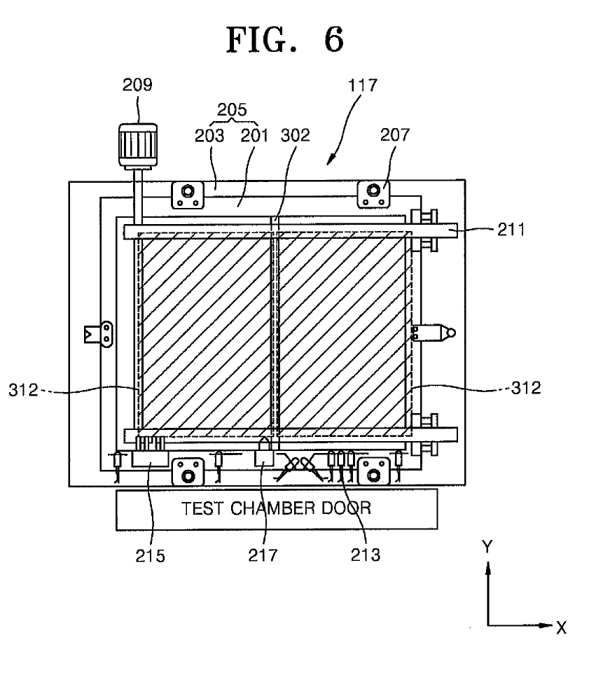

Hereinafter, test chamber 117 of test handler 100 according to an embodiment of the invention will be described in some additional detail. Test handler 100 includes a thermal isolator 312 (FIG. 6) associated with test chamber 117 in order to maintain temperature within test chamber 117 even when test chamber 117 and test head 135 are separated. In other words, thermal isolator 312 maintains temperature within test chamber 117 by sealing the test chamber 117 from the outside environment when test chamber 117 and test head 135 are separated.

In one embodiment of the invention, thermal isolator 312 may be implemented as a sliding shutter, however, the present invention is not limited to only this configuration. The number of semiconductor devices to be tested in test chamber 117 will vary according to the shape and size of test trays T or with the capacity of the test chamber 117. Thus the scope of the present invention is not defined by the number of semiconductor devices capable of being tested at any one time.

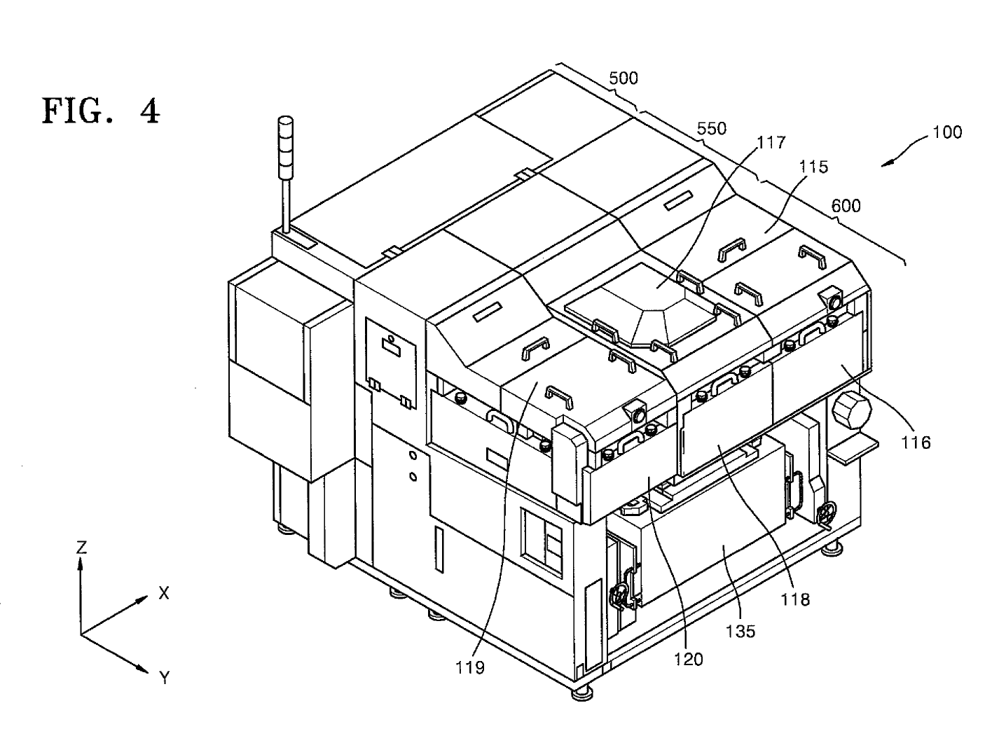

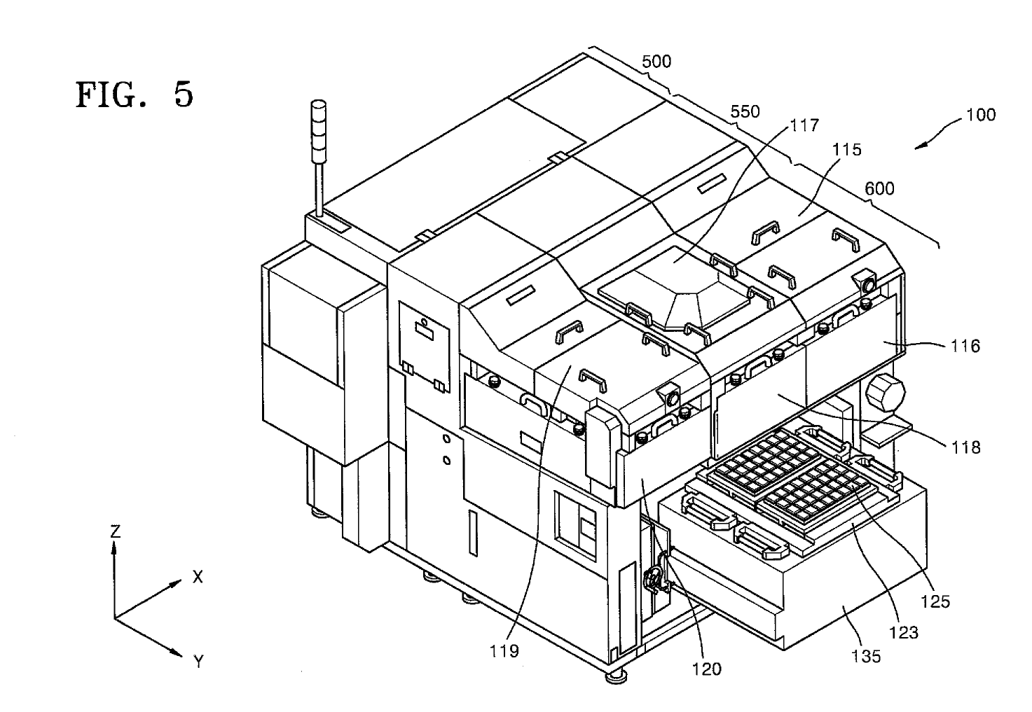

FIG. 4 is a rear perspective view further illustrating test handler 100 in which a test chamber and a test head are combined according to an embodiment of the invention. In contrast, FIG. 5 is another rear perspective view further illustrating test handler 100 of FIG. 4 in which the test chamber and the test head are separated.

Within these two figures, soak chamber 115 is assumed to preheat or pre-cool semiconductor devices S mounted in test trays T according to a defined test temperature. Soak chamber 115 is installed to one side of test handler 100 and includes a door 116.

A test chamber 117 is installed to one side of soak chamber 115 and between soak chamber 115 and exist chamber 119, and includes a door 118. In test chamber 117, the quality of semiconductor devices may be tested by connecting the semiconductor devices transported from soak chamber 115 along the X-axis direction with a test head 135 disposed below and separated from test trays T. In one illustrative example, test head 135 includes a test board 123 including test one or more sockets 125.

When the test trays T enter an upper portion of test board 123 connected to the test head 135 and are arranged in the upper portion of test board 123, as illustrated in FIG. 3, mechanical pressure is applied to test plate 121 in the Z-axis direction to connect each semiconductor device S in the test trays T to a corresponding test socket 125 of test board 123 in order to test the semiconductor device S.

Exit chamber 119 is installed to the other side of test chamber 117, is adapted to return the semiconductor devices to the test trays T, and includes a door 120. The tested semiconductor devices may return to normal temperature (i.e., room temperature) in exit chamber 119.

Test head 135 is disposed separately below the test trays T as illustrated in FIGS. 4 and 5, and thus disposed, may move in the X, Y, and/or Z direction(s) to combine with and separate from test handler 100, as needed. When test head 135, test board 123, and/or test socket 125 require repair or change out, or when a testing defect related to test handler 100 must be fixed, the test head 135 may be separated from test handler 100 as illustrated in FIG. 5. In such a case, the conventional test chamber could not maintain temperature.

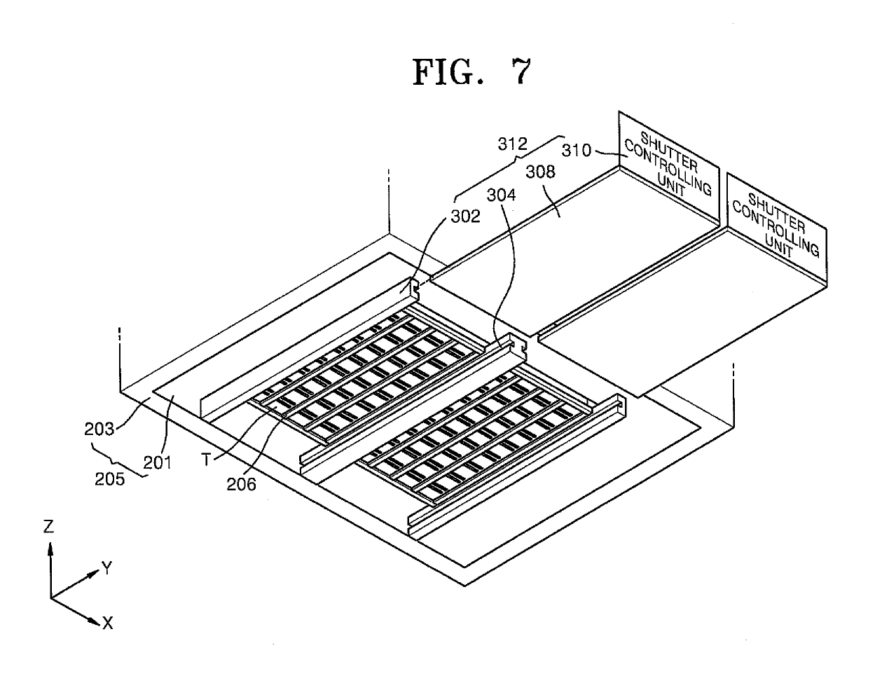

However, a thermal isolator 312 (see FIGS. 6 and 7) included in a test chamber 117 according to an embodiment of the invention can maintain a test temperature even when test chamber 117 and test head 135 are separated to facilitate this type of maintenance operation. A test chamber 117 including thermal isolators 312 will be described in some additional detail with reference to FIGS. 6 through 8.

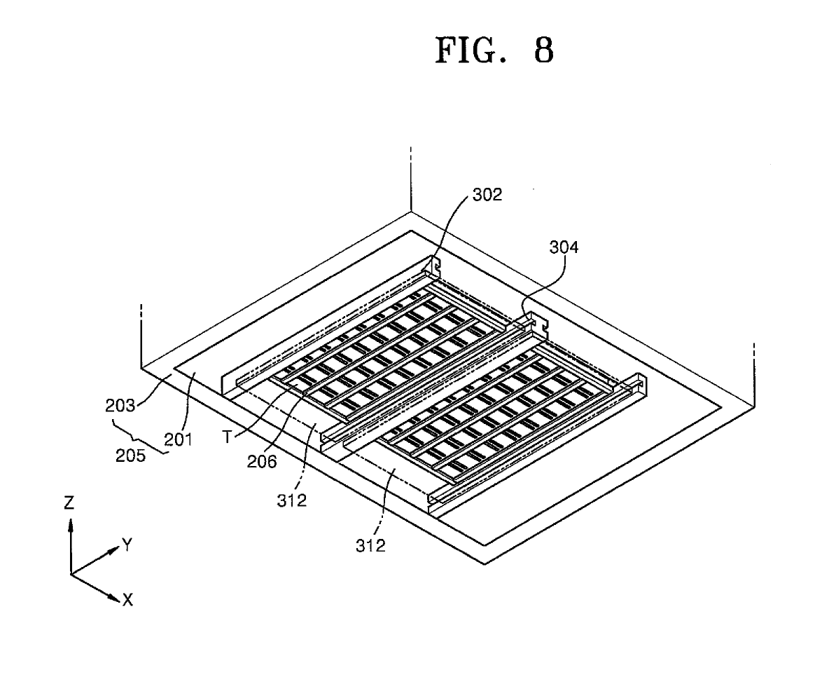

FIG. 6 is a plane view further illustrating test chamber 117 according to an embodiment of the invention. FIGS. 7 and 8 are related perspective views as seen from a bottom surface and illustrating separated and combined states for test chamber 117 according to an embodiment of the invention.

Test chamber 117 includes one or more thermal isolators 312. In the illustrated embodiment of FIG. 6, test chamber 117 includes a body 205 including a test tray supporting body 201 and a test tray main body 203. Test tray supporting body 201 and test tray main body 203 are connected to a connecting member 207 including a spring. A supporting unit 206 directly supporting the test tray T is installed in test tray supporting body 201.

In FIG. 6, supporting unit 206 is not shown for clarity of illustration. Test tray supporting body 201 and test tray main body 203 may be formed as one unit. The test tray T is transported by means of a drive motor 209 and a test tray turn-ON belt 211 in the X direction. The transported test tray T may be safely mounted within a test chamber 217 through operation of a position sensor 213, a position stop sensor 215, and a tray lock pin 217.

A thermal isolator 312 adapted to seal or open test chamber 117 is installed on a rear surface of the body 205 of test chamber 117. Two thermal isolators 312 are installed in the illustrated example by partitioning test chamber 117 in half. However, the actual number of the thermal isolator(s) 312 may be as many as necessary. Thermal isolator 312 includes a shutter guide portion 302, a groove 304, a shutter 308, and a shutter controlling portion 310. Shutter controlling portion 310 is connected to a controlling unit (not shown) of test handler 100. Shutter controlling portion 310 drives and controls shutter 308 and may be installed on a rear surface of body 205.

Shutter guide portion 302 may be attached on a rear surface of body 205 in a Y direction. Shutter guide portion 302 and body 205 may be formed as one unit, but here, they are denoted with different reference numerals for convenience of explanation. Groove 304 along which shutter 308 may move in relation to shutter guide portion 302. Shutter 308 can be used for both high and low temperature insulation and will be made from a material that does not thermally deform.

Test chamber 117 can be sealed or opened by moving shutter 308 through groove 304 in shutter guide portion 302 using shutter controlling unit 310. Shutter 308 used in the illustrated embodiment of the invention is an automatic sliding type shutter that can move automatically and can be wound around a wheel (not shown) in shutter controlling unit 310. Of course, shutter 308 may have many other specific forms. In one embodiment the surface of shutter 308 may be curved slightly.

Consequently, test chamber 117 according to an embodiment of the invention may be sealed or opened using thermal isolator 312 even when test head 135 is separated therefrom, thereby maintaining constant testing conditions, such as high or low temperature.

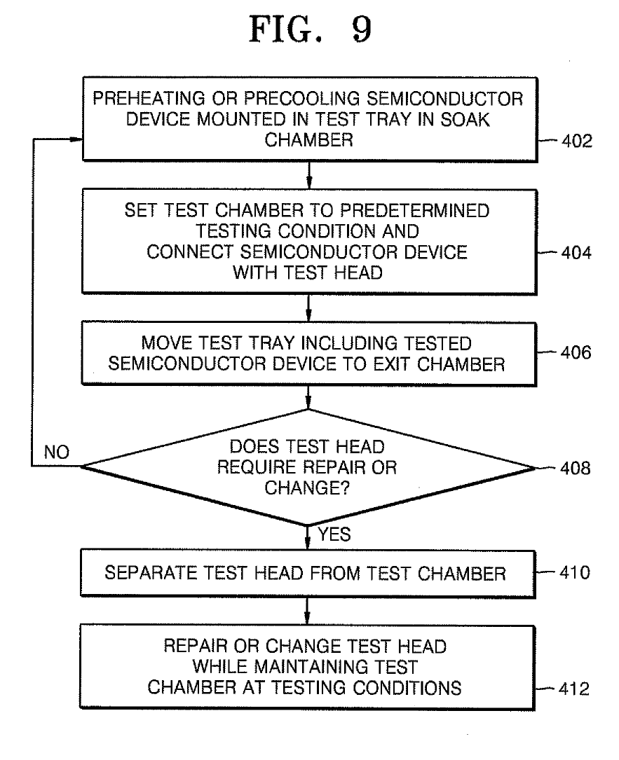

FIG. 9 is a flow chart summarizing a method of testing a semiconductor device using a test handler according to an embodiment of the invention.

Semiconductor devices are mounted in a test tray using the front portion or the middle portion of the test handler. The semiconductor devices mounted in the test trays are preheated or pre-cooled in a soak chamber (402). Then, when a test chamber is set to defined test conditions (possibly including a high or low temperature) and the semiconductor devices are mounted in the test trays, the test chamber is combined with the test head in order to test the semiconductor devices. That is, the semiconductor devices are tested using the test plate by connecting each semiconductor device to a corresponding test socket of a test board (404). The test tray including tested semiconductor devices is then moved to an exit chamber (406).

Then, it is determined whether the test head including the test sockets or the test board needs to be repaired or changed, or whether a testing defect associated with the tester has occurred (408). If the test head does not have to be repaired or changed testing may continue (402 through 406 repeated) using additional test trays.

However, if the test head needs to be repaired or changed or there is a testing defect, the test head may be separated from the test chamber (410). Yet, the test chamber may remain sealed using an integral thermal isolator while the test chamber is separated during maintenance operations (412). Thus, the test conditions defined in the testing chamber, including a high or low temperature, may be maintained constant by sealing the test chamber. When the test head is repaired or changed or when a testing defect is fixed, the test chamber may again be combined with the test head by opening the thermal isolator.

According to the present invention, a test handler includes a thermal isolator installed in a lower portion of a test chamber. Accordingly, the test handler according to the present invention may maintain constant testing conditions, including a high or low temperature, by sealing the test chamber when a test head including a test board and test sockets requires repair or change-out, or when a testing defect must be otherwise addressed. Thus, since the testing conditions within the test chamber are maintained, the working ratio of the tester is significantly increased, thereby significantly increasing the productivity of the overall testing process.

While the present invention has been particularly shown and described with reference to exemplary embodiments thereof, it will be understood by those of ordinary skill in the art that various changes in form and details may be made therein without departing from the scope of the present invention as defined by the following claims.

What is claimed is:

1. A test handler for testing a semiconductor device, the test handler comprising a test chamber testing the semiconductor device under a test temperature by electrically connecting the semiconductor device mounted in a test tray with a test head disposed under and separated from the test tray,
wherein the test chamber includes a thermal isolator maintaining the test temperature constant when the test chamber is separated from the test head.

2. The test handler of claim 1, wherein the thermal isolator is installed below the test chamber and comprises a shutter sealing or opening the test chamber.

3. The test handler of claim 1, wherein the thermal isolator comprises a shutter guide portion disposed on a rear surface of a body of the test chamber, a groove formed in the shutter guide portion, and a shutter that seals or opens the test chamber by moving through the groove.

4. The test handler of claim 1, wherein the thermal isolator comprises a plurality of the thermal isolators installed by partitioning the test chamber.

5. The test handler of claim 1, further comprising:
a soak chamber preheating or pre-cooling the semiconductor device mounted in the test tray to the test temperature disposed to one side of the test chamber.

6. The test handler of claim 5, further comprising:
an exit chamber returning the test tray and tested semiconductor device to a normal temperature and disposed to another side of the test chamber.

7. A test handler for testing a semiconductor device, the test handler comprising:
a soak chamber preheating or pre-cooling the semiconductor device mounted in a test tray to a test temperature;
a test chamber disposed to one side of the soak chamber, receiving the semiconductor device from the soak chamber, combining with a test head to electrically connect the semiconductor device during testing under the test temperature, and separating from the test head following testing of the semiconductor device; and
an exit chamber disposed to one side of the test chamber, receiving the semiconductor device following testing and returning the semiconductor device to a normal temperature,
wherein a thermal isolator installed in the test chamber maintains the test temperature constant while the test chamber is separated from the test head.

8. The test handler of claim 7, wherein the thermal isolator comprises a shutter disposed below the test chamber and sealing or opening the test chamber.

9. A test handler for testing a semiconductor device, the test handler comprising:
a soak chamber preheating or pre-cooling the semiconductor device mounted in a test tray under a defined test temperature;
a test chamber disposed to one side of the soak chamber, receiving the semiconductor device transported from the soak chamber in an X direction, and combining with a test head disposed below and separated from the test chamber during testing of the semiconductor device under the test temperature by movement of the test head in a Z direction; and
an exit chamber disposed to one side of the test chamber, receiving the semiconductor device in the X direction, and returning the semiconductor device to a normal temperature,
wherein the test chamber comprises a thermal isolator maintaining the test temperature constant when the test chamber is separated from the test head, the thermal isolator being installed in a body of the test chamber to move in a Y direction to seal or open the test chamber.

10. The test handler of claim 9, wherein the thermal isolator comprise a shutter.

11. The test handler of claim 10, wherein a shutter guide portion is attached on a rear surface of the body of the test chamber in a Y direction, and a groove is formed in the shutter guide portion such that the shutter moves in the groove.

12. A method of testing a semiconductor device, the method comprising:
preheating or pre-cooling the semiconductor device mounted in a test tray in a soak chamber at a test temperature;
testing the semiconductor device in a test chamber under the test temperature by electrically connecting the semiconductor device with a test head installed separately from the test chamber;
moving the test tray including the tested semiconductor devices to an exit chamber following testing;
upon determining that the test head requires repair or change, or that a testing defect has occurred, separating the test head from the test chamber but maintaining the test temperature in the test chamber when the test chamber is separated from the test head.

13. The method of claim 12, wherein maintaining the test temperature in the test chamber comprises sealing the test chamber with a thermal isolator installed in the test chamber.

14. The method of claim 13, wherein the thermal isolator comprises a shutter.

15. The method of claim 13, further comprising:
following separation of the test head from the test chamber to repair or changed the test head or to address a testing defect, re-opening the test chamber by moving the thermal isolator and re-combining the test head and test chamber.
